(19) United States
(12) Patent Application Publication
(10) Pub. No.: US 2008/0079169 A1
(43) Pub. Date: Apr. 3, 2008

(54) Manufacturing method for semiconductor device, semiconductor device, substrate processing system, program and memory medium

(75) Inventor: Kaoru MAEKAWA, Albany, NY (US)

Correspondence Address: MASUVALLEY & PARTNERS, 8765 AERO DRIVE, SUITE 312, SAN DIEGO, CA, 92123, US

(73) Assignee: Tokyo Electron Limited, Tokyo (JP)

(21) Appl. No.: 11/904,970

(22) Filed: Sep. 27, 2007

(30) Foreign Application Priority Data
Sep. 28, 2006 (JP) 2006-265285

(51) Int. Cl. H01L 23/52; B05C 11/00; H01L 21/4763

(52) U.S. Cl. 257/773; 118/697; 438/627; 257/E23.141; 257/E21.495

(57) ABSTRACT

The objective of the present invention is to prevent damage to an interlayer insulation film when forming a structure having a first wiring and a second wiring, which is laminated on the first wiring and connected to the first wiring, and are filled in the interlayer insulation film. After forming a first pattern corresponding to the first wiring on a first sacrificial film, fill a metal in the first pattern. Next, after forming a second sacrificial film on the first sacrificial film, form a second pattern corresponding to the second wiring, and fill a metal in the second pattern. Thereafter, remove the first sacrificial film and the second sacrificial film to form the first wiring and the second wiring, and further form the interlayer insulation film so as to coat the barrier film after coating the first wiring and the second wiring.

### TECHNICAL FIELD

The present invention relates to a method for manufacturing a semiconductor device to laminate a first wiring and a second wiring for an interlayer insulation film, and also to the semiconductor device.

### BACKGROUND OF THE INVENTION

As a process to form a wiring in a semiconductor device, the dual damascene process is known and the process is such that after forming a groove (also called a trench) to fill a nth layer of first wiring in an interlayer insulation film, and a via hole to fill a second wiring (also called an electrode) which becomes an electrode to connect the nth layer first wiring and n−1^{st} layer first wiring in a series of processes, thereby simultaneously forming the first wiring and the second wiring for via by filling a wiring metal, for example Cu (copper), in the depressions.

FIG. 8 is a process diagram specifically showing the dual damascene process described above, 101 in the figure is an interlayer insulation layer, and 102 in the figure is a diffusion barrier film for a wiring metal. After forming a trench 103 on the interlayer insulation film 101 (FIG. 8 (a)), a via hole 104 is formed which is connected to a lower layer wiring (FIG. 8(b)), fill wiring metal 106 in the trench 103 and the via hole 104 after forming a barrier film 105 to prevent wiring metal diffusion on the surface of the trench 103 and the via hole 104 (FIG. 8 (c)), then forming the first wiring 107 and the second wiring 108 by removing excess metal by CMP (Chemical Mechanical Polishing) (FIG. 8 (d)).

In recent years, the parasitic capacity of an interlayer insulation film has become an important element to increase the performance of wiring with a miniaturization of the semiconductor device. For this reason, lowering the dielectric constant of the interlayer insulation film itself has been promoted, and CDO (Carbon Doped Oxide), such as SiCO which is an added molecule mainly consisting of carbon in SiO2, or a certain type of organic matter has been used recently as a material for low dielectric interlayer insulation film material. For example, the dielectric constant of the CDO is generally approximately 3.0. Further, the low dielectric constant may be realized by forming the low dielectric interlayer insulation film consisting from these materials as a porous body introduced with a number of pores.

By the way, when performing the dual damascene process, there are cases where directly performing the etching process for example, by using plasma to the interlayer insulation film to form the trench and the via hole, or performing the ashing by using O2 plasma to remove the resist film formed on the interlayer insulation film as a sacrificial film to form the trench and the via hole. When the interlayer insulation film is formed by an organic matter, the processing of the interlayer insulation film may be performed by forming a hard mask consisting of SiO2 (oxide silicon), SiN (silicon nitride), SiC (silicon carbide) and the like on the interlayer insulation film by spattering using plasma. In order to prevent the metal forming the first and the second wiring from diffusing into the interlayer insulation film, a metal barrier layer (barrier metal) is formed on the surfaces of the trench and the via hole. And, after forming the trench and the via hole on the interlayer insulation film in nth layer, the surface of the first wiring in n−1^{st} layer exposed on the bottom of the via hole may be cleaned (pre-cleaning) by using plasma before forming the barrier layer to this interlayer insulation film.

However, when the interlayer insulation film is exposed to plasma at each process described above, the interlayer insulation film is damaged, for example as shown in the formula below, thereby the group contains carbon, such as a methyl group introduced in the material to form the film for reducing the dielectric constant, is removed, and the hydroxyl group generated from an O2 molecule which exists in the process atmosphere is introduced instead of the group containing carbon. For example, when a process is performed by using O2 plasma, the hydroxyl group, which is generated from an O2 molecule in the plasma, will be introduced.

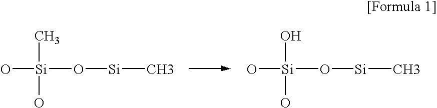

The carbon is reduced in this way, and as a result of the hydroxyl group being instroduced, the interlayer insulation film absorbs moisture, thereby its dielectric constant increases from its original value. When the interlayer insulation film is formed as a porous body as described above and plasma enters a pore, the interlayer insulation film can easily be damaged and the dielectric constant is likely to increase.

As a method to avoid the problem of increasing the dielectric constant of the interlayer insulation film, in the non-patent document 1, the first insulation film around the second wiring is removed by etching after forming the first wiring (electrode) and the second wiring covers the first wiring in the first insulation film formed on the substrate. At this time, the second wiring acts as a mask, the first insulation film around the first wiring remains without being removed, and supports the second wiring. The method for forming the dual damascene structure is proposed by thereafter supplying the second interlayer insulation film forming a material around each wiring and filling each wiring back to this second insulation film. However, the dielectric constant may not be sufficiently reduced because the dielectric body damaged by etching remains around the first wiring as described above.

The patent document 1 describes the following process. First, form a metal layer which becomes a first wiring, on the substrate in advance, then form a barrier layer so as to surround this metal layer, thereafter form an interlayer insulation film so as to cover this barrier layer. Next, form a metal layer which becomes a second wiring on the first wiring, then form a barrier layer so as to surround this metal layer, thereafter perform a damascene process to form the interlayer insulation film so as to cover the barrier layer.

However, the method in this patent document 1 is a so-called single damascene process to form the layer containing the first wiring and the layer containing the second wiring separately, therefore, a number of processes are required until the first wiring and the second wiring are formed. Also, according to this method, there is a problem of low conductivity between the wirings because the barrier layer is mediated between the first wiring and the second wiring.

Also, the patent document 2 discloses a method which provides a sacrificial film with a pattern on the substrate, filling a conductor, which becomes wiring, in this pattern, removing excess conductor by CMP, and removing the sacrificial film to fill the dielectric body, thereafter forming an insulation film so as to cover this dielectric body and the conductor.

However, although it is not indicated in the specification, it is necessary to form a barrier layer, that is an insulation film, across the substrate to insulate the substrate and the conductor before filling the conductor after forming a pattern on the sacrificial film in the above described method based on the technical common knowledge, therefore, it is thought that a structure laminating the substrate, the barrier layer, conductor (wiring) in order is formed after filling the conductor. And, when planarizing such laminate structure by CMP, a problem depends on the roughness and fineness of the wiring occurs. Explaining this problem specifically, a phenomenon called erosion that the insulation film, which should not be removed, is removed along with the conductor may occur when the wiring is thin and dense, and a phenomenon called dishing, in that the wiring, which should not be removed, is removed may occur at the removal of the barrier layer when the wiring is thick and rough.

In addition, the patent document 3 also discloses a method to form an interlayer insulation film around a wiring after forming the wiring on a substrate, however, this relates to a single damascene process as the invention of the patent document 1, which has a problem that the number of required processes is too high. Also, the manufacturing method of a semiconductor device described in the patent document 4 includes a process for etching the interlayer insulation film, therefore it does not solve the issues described above.

Also, another attempt to prevent damage to the low dielectric constant insulation film has been made, for example, the patent document 2 discloses a high temperature He/H2 ashing technique which is applied to resist separation. However, not only the damage to the interlayer insulation film can not be completely prevented using this technique, but also there is a problem of decreasing in separation speed or separation property of the resist. Also, in the process which may possibly damage the interlayer insulation film described above other than the removal of the resist, it is difficult to prevent damage completely.

### [Patent document 1] Japanese unexamined patent application No. 2005-38971 (paragraphs 0039 to 0042, FIGS. 3 and 4)

[Patent document 2] Japanese unexamined patent application No. H11-219955 (paragraph 0014, FIGS. 1 and 2)

### [Patent document 3] Japanese unexamined patent application No. 2001-85519 (Paragraphs 0024, 0025, and FIGS. 8 to 12)

### [Patent document 4] Japanese unexamined patent application No. 2004-71621 (Paragraphs 0011 and 0013)

[Non patent document 1] (S. Nitta et al. “Successful dual damascene integration of extreme low k material (k<2.0) using a novel gap fill based integration scheme” IEDM2004)
[Non patent document 2] (A. Matsushita et al. “Low damage ashing using H2/He plasma for porous ultra Low-k” Proceeding IITC '03 pp 147-149)

The objective of the present invention is to provide a technique capable of preventing the increase of dielectric constant in an interlayer insulation film by preventing the damage to the interlayer insulation film when forming a structure in which a first wiring and a second wiring laminated on the first wiring and electrically connected to the first wiring are filled in the interlayer insulation film.

### BRIEF SUMMARY OF THE INVENTION

The manufacturing method for a semiconductor device according to the present invention for forming a first wiring on an interlayer, and a second wiring laminated onto this first wiring and electrically connected to the first wiring and the wiring on an upper layer, the method includes a process for forming a conductive lower diffusion barrier film on a substrate to prevent the metal consisting of the first wiring from diffusing into a lower interlayer, a process for forming a first sacrificial film on the lower diffusion barrier film and forming a first pattern, which is a depression corresponding to the first wiring, on the first sacrificial layer, a process for filling metal in the first pattern and forming the first wiring, a process for forming a second pattern which is a depression corresponding to the second wiring so as to expose the first wiring on a second sacrificial layer after forming the second sacrificial film on the first sacrificial film and the first wiring, a process for forming a second wiring by a filling metal in the second pattern, a process for removing the first sacrificial film and second sacrificial film, and a process for forming an upper diffusion barrier film to coat the first wiring and the second wiring in order to prevent the metal consisting of each wiring from diffusing into the interlayer insulation film, and forming an interlayer insulation film so as to coat the upper diffusion barrier film wherein the projection domain of the second wiring to the substrate is smaller than the projection domain of the first wiring to the substrate.

In the manufacturing method, the process for forming the upper diffusion barrier film is a process, for example, for forming the upper diffusion barrier, that is an insulation film, so as to coat the first wiring, the second wiring and lower diffusion barrier film, and the method also includes, for example, a process for forming the first diffusion barrier film so as to coat the first wiring and the second wiring, a process for etching the first diffusion barrier film and the lower diffusion barrier film, and a process for forming a second diffusion barrier film which is an insulation film to coat the first wiring, second wiring, and the surface of a substrate, and the upper diffusion barrier film consists of the first diffusion barrier film and the second diffusion barrier film. The thickness of the second diffusion barrier film is, for example, 5 to 30 nanometers (“nm”).

And, a process for providing the seed layer, that is a conductor, on the lower diffusion barrier film is further included before forming the first sacrificial film. The process to form the first wiring may be performed by electrolytic plating to apply a voltage to this seed layer. In such a case, the process to form the second wiring may be performed by electrolytic plating to apply voltage to the first wiring through the seed layer. The removal of the first sacrificial film and the second sacrificial film is performed, for example, by wet etching, and, for example, the first sacrificial film and the second sacrificial film consists of the same material.

The semiconductor device according to the present invention is manufactured by using the manufacturing method of the semiconductor device described above, and the substrate processing system according to the present invention consists of a plurality of device groups and is provided with the control portion to control so as to perform the manufacturing method described above. Also, the program according to the present invention operates on a computer to control the plurality of semiconductor manufacturing devices so as to perform the manufacturing method when it is executed, and the memory medium according to the present invention stores the program described above.

According to the present invention, after the first wiring is formed in the first sacrificial film and then the second wiring is on the second sacrificial film provided on the first sacrificial film, the first sacrificial film and the second sacrificial film are removed by wet etching, thereafter the interlayer insulation film is formed so as to cover the first wiring and the second wiring, thereby the projection domain of the second wiring to the substrate is smaller than the projection domain of the first wiring to the substrate. Therefore, in order to form wiring in the conventional dual damascene process, it is necessary to perform a process that etching or ashing the interlayer insulation film under the environment in which plasma is generated, however, since the interlayer insulation film is formed so as to cover the wiring after forming the wiring as described above, the damage to the interlayer insulation film is prevented because there's no necessity for such process. Also, since the projection domain of the second wiring to the substrate is smaller than the projection domain of the first wiring to the substrate, the second wiring acts as a mask when removing the sacrificial film, thereby preventing the sacrificial film, which is damaged from processes such as etching, from remaining around the first wiring. As a result, an increase in the parasitic capacity of the interlayer insulation film that covers the wiring may be prevented, and also the reliability of the wiring can be improved. Also, a decrease in the yield of the semiconductor device, which is formed by using these wirings, may be prevented.

### BRIEF DESCRIPTION OF THE DRAWINGS

FIG. 1 is a process diagram of a manufacturing method of a semiconductor device according to the present invention.

FIG. 2 is a process diagram of a manufacturing method of a semiconductor device according to the present invention.

FIG. 3 is a process diagram of a manufacturing method of a semiconductor device according to the present invention.

FIG. 4 is a process diagram of a manufacturing method of a semiconductor device according to the present invention.

FIG. 5 is a process diagram of a manufacturing method of a semiconductor device according to the present invention.

FIG. 6 is an illustration of an electrolyte plating performed in an embodiment of the present invention.

FIG. 7 is a block diagram of a substrate processing system to perform a manufacturing method according to the present invention.

FIG. 8 is a process diagram explaining a conventional dual damascene process.

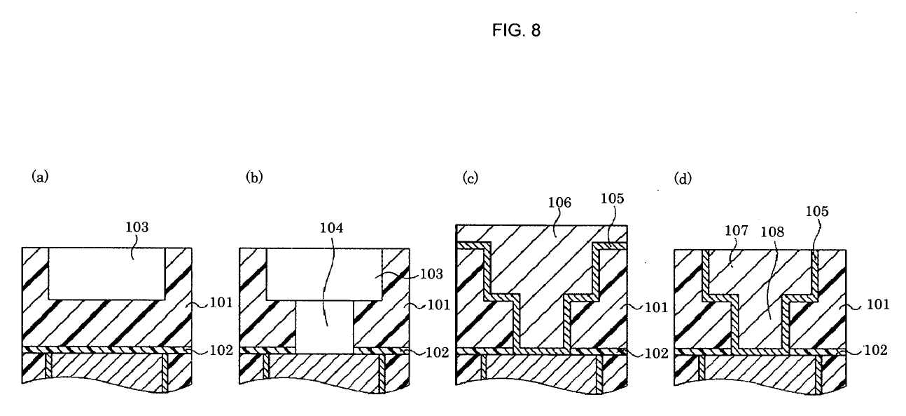

### DETAILED DESCRIPTION OF THE INVENTION

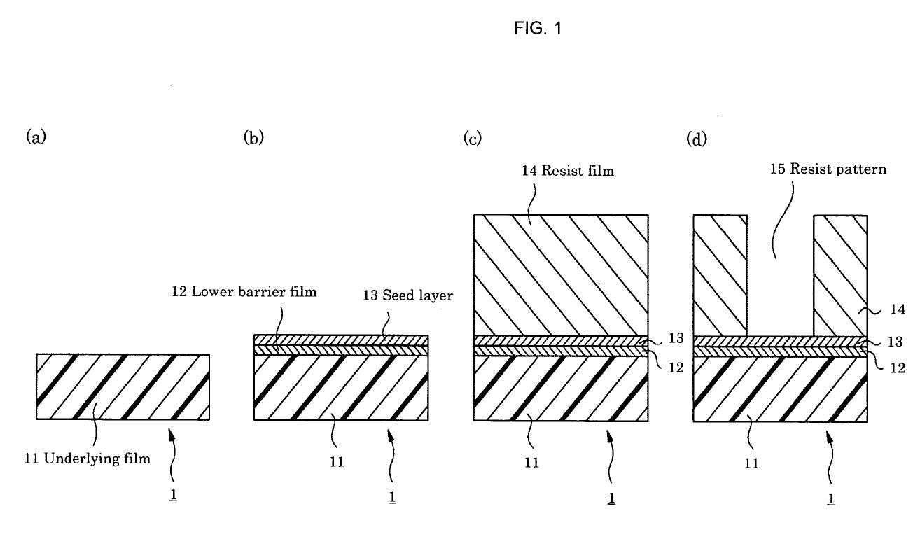

A dual damascene process, an embodiment of a manufacturing method of a semiconductor device according to the present invention, is explained referring to FIGS. 1 to 5. 1 in FIG. 1 (a) is a substrate (underlying substrate) which has an underlying film 11, and, for example, a semiconductor element (not shown), such as a transistor, is formed thereon.

### (Step 1: Forming of a Lower Barrier Film 12 and a Seed Layer 13)

First, as shown in FIG. 1 (b), a lower barrier film 12 is formed, which is a lower diffusion barrier film consisting of, for example, conductive TiN (titanium nitride), on an underlying film 11, and then a seed layer 13 is formed, consisting of, for example Cu (copper) on the lower barrier film 12. The lower barrier film 12 is a lower diffusion barrier film to prevent a metal which consists a wiring in a subsequent process and a metal which consists of the seed layer 13 from diffusing onto the underlying film 11, and the seed layer 13 functions as an electrode when performing an electrolytic plating later.

The lower barrier film 12 may consist of a metal film, such as, Ta (tantalum), TaN (tantalum nitride), Ti (titanium) TiN, W (tungsten), WN (tungsten nitride), and Ru (ruthenium). Also, each of these films may be laminated in plurality as a laminated film. And the seed layer 13 functions as an electrode when performing the electrolytic plating, and it may be constituted by Ru, other than Cu.

### (Step 2: Forming of a Resist Film 14 and a Resist Pattern 15)

Thereafter, as shown in FIG. 1 (c), for example, a resist film 14 which is a photosensitive organic film, is formed on the seed layer 13, then a development process is performed after exposing the resist film 14 according to an intended wiring pattern on the resist film 14 as shown in FIG. 1 (d), and a resist pattern 15 is formed so as to expose the seed layer 13 on the bottom face. The resist film 14 is equivalent to the first sacrificial film referred in the claim. Also, the resist pattern 15 is equivalent to the trench described in the background of the invention, and the first wiring in formed in this pattern 15.

### (Step 3: Forming of a First Wiring 21)

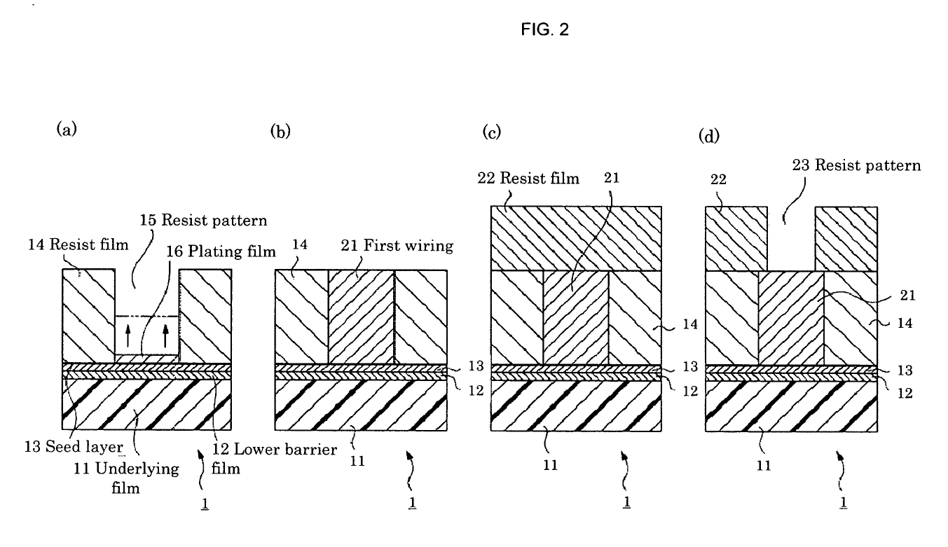

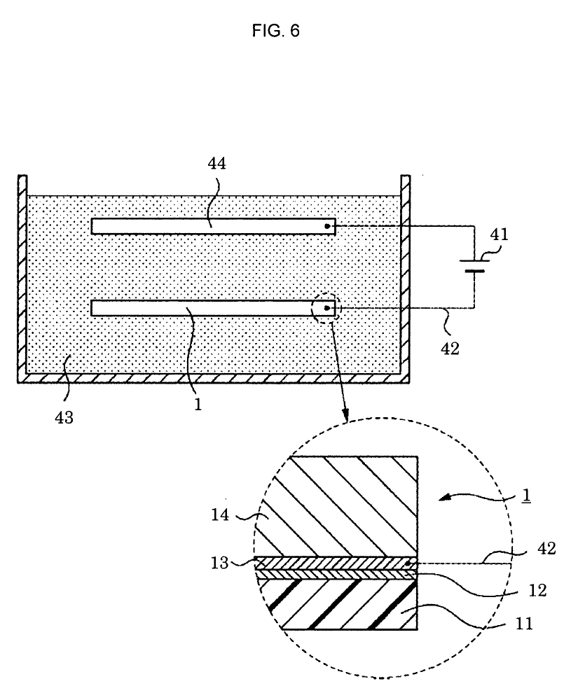

Accordingly, the seed layer 13 and a cathode are electrically connected by connecting an edge of the seed layer 13 to an external wiring 42 which is electrically connected to the cathode of a DC power supply 41. And, dip the substrate 1 into a solution 43 (shown in FIG. 6) containing, for example, Cu ion and sulfate ion, arrange a cathode electrode 44 connected to the anode of the DC power supply 41 in a way that faces the substrate 1 in the solution 43, and apply voltage to each of the cathode electrode 44 and the seed layer 13. When the voltage is applied, the seed layer 13 becomes an anode electrode and progresses the electrolyte plating, Cu accumulates on the surface of the seed layer 13 which is exposed on the bottom of the resist pattern 15, a plating film 16 consisting of the Cu formed in the resist pattern 15, as shown in FIG. 2 (a), and grows as it fills the resist pattern 15.

Because the plating film 16 grows the resist pattern 15 with upward directionality and prevents an irregular growth, a void in the first wiring 21 forming from these plating films 16 may be prevented. As a result, the deterioration in the strength and the conductivity of the wiring 21 may be prevented. Also, because the plating film 16 grows with the directionality as described above, it can prevent an additive for controlling the direction of growth of the plating layer from mixing into, for example, a solution containing Cu ion to perform electrolytic plating. Therefore, incorporation of the additive into the first wiring 21 can be prevented, thereby the deterioration in the strength or the conductivity of the first wiring 21 can also be prevented.

For example, stop the application of voltage to the seed layer 13 and the cathode electrode 44 after a predetermined time is elapsed. Thereafter, remove the excess plating film 16 which overflowed from the resist pattern 15 and formed on the surface of the resist film 14, by CMP, and then the first wiring 21 is formed by planarizing the surface of the plating layer 16 as shown in FIG. 2 (b).

### (Step 4: Forming of a Resist Film 22 and a Resist Pattern 23)

Consequently, form the resist film 22, which is a second sacrificial layer, on the resist film 14 and the wiring 21 as shown in FIG. 2 (c), thereafter, form the resist pattern 23 for forming a second wiring in a way that the first wiring 21 is exposed on the bottom as shown in FIG. 2 (d). The resist pattern 23 is equivalent to the via hole described in the background of the invention section, a wiring acting as an electrode is formed and the projection domain on the lower side is formed smaller than the projection domain on the lower side of the first wiring.

### (Step 5: Forming of a Second Wiring 25)

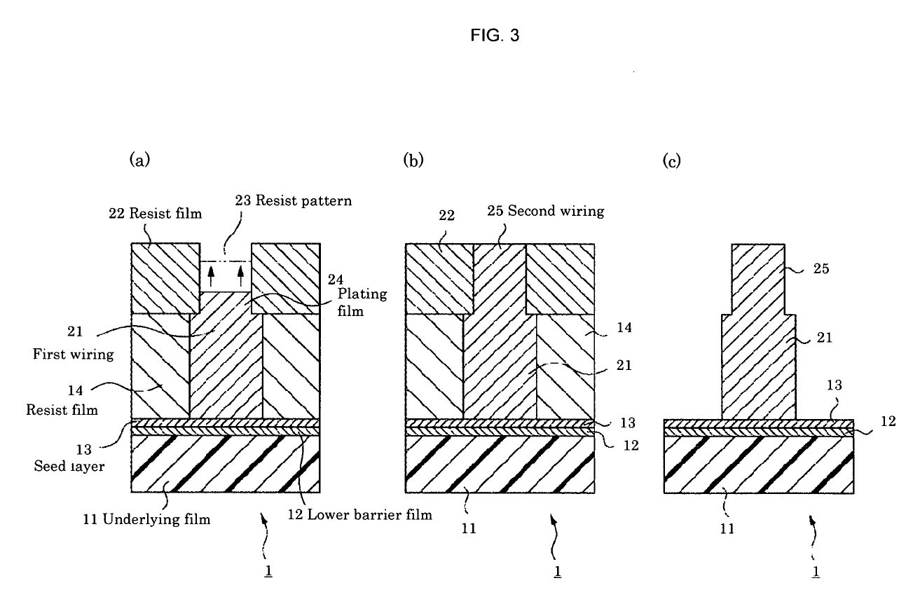

After forming the resist pattern 23, electrically connect the cathode of the power supply 42 and the seed layer 13 again by connecting the seed layer 13 to the external wiring 42 as shown in FIG. 6, dip the substrate 1 into the solution 43, and apply voltage to the seed layer 13 and the cathode electrode 44 by arranging the cathode electrode 44 so as to face to the substrate 1, thereby the electrolyte plating is performed. When the voltage is applied, the wiring 21 electrically connected to the seed layer 13 becomes an anode electrode, Cu is accumulated on the surface of the wiring 21 exposed on the bottom of the resist pattern 23 as shown in FIG. 3 (a), a plating film 24 consisting of Cu is formed in the resist pattern 23, and it grows so as to fill the resist pattern 23.

For example, the application of voltage to the cathode electrode 44 and the seed layer 13 is stopped after a predetermined time is elapsed. Thereafter, excess plating film 24 which has overflowed from the resist pattern 23 and formed on the surface of the resist film 22, is removed by CMP, and then the second wiring 25 (electrode) is formed by planarizing the surface of the plating film 24 as shown in FIG. 3 (b).

As the plating film 16, the plating film 24 also grows the resist pattern 23 with upward directionality, thereby an occurrence of a void can be prevented in the second wiring 25 formed from this plating film 16.

### (Step 6: Removal of the Resist Films 14 and 22, and Forming an Upper Barrier Film 31)

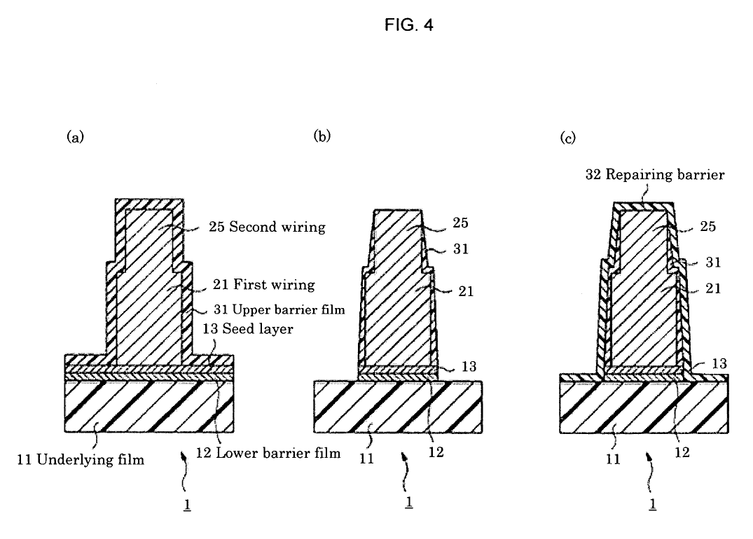

After forming the second wiring 25, remove the resist film 14 and the resist film 22 by, for example, wet etching as shown in FIG. 3 (c), and then form the upper barrier film 31 consisting of, for example, SiC in a way that the lower barrier film 12, the first wiring 21, the second wiring 25 and the seed layer 13 are covered (FIG. 4(a)). The upper barrier film 31 and a repairing barrier 32 described later have a function to prevent Cu that consists of the first wiring 21 and the second wiring 25 from diffusing to an interlayer insulation film 33 described later. After forming the upper barrier film 31, perform dry etching to remove, for example, the upper barrier film 31 and lower barrier film 12 covering the underlying film 11 around the first wiring 21, and expose the underlying film 11 (FIG. 4 (b)).

The upper barrier film 31 may consist of an insulation film such as SiN (silicone nitride), other than SiC. Also, it may consist of various metals which are listed as materials, such as TiN, that can comprise the lower barrier film 12 as described above. In addition, it may be a laminated layer, laminating films made of these materials as the lower barrier film 12.

### (Step 7: Forming of a Repairing Barrier Film 32)

Next, form the repairing barrier film 32 which is the second diffusion barrier film consisting of, for example, SiC, on the substrate 1 (FIG. 4(c)). This repairing barrier film 32 has a role to repair the upper barrier film 31 and prevent the Cu which consists of the first wiring 21 and the second wiring 25 on the interlayer insulation film, from diffusing by covering the upper barrier film 31 which is thinned by the dry etching, or by covering the first wiring 21 and the second wiring 25 instead of the upper barrier 31 which is lost by dry etching. The repairing barrier film 32 also prevents the metals consisting of the seed layer 13 from diffusing in the interlayer insulating layer by covering around the seed layer 13. And, its thickness is approximately, for example, 5 to 30 nm.

In order to prevent the metal consisting of the first wiring 21 and the second wiring 25 from diffusing in the interlayer insulation film, the barrier film to cover those is required to have a certain degree of thickness. However, it is preferable not to mediate an extra film in between the interlayer insulation film 33 and the underlying film 11 which are formed to cover each wiring later, to prevent the change in the dielectric constant of the interlayer insulation film 33. When performing the etching after forming the barrier film 31, the barrier films 31 and 12 on the underlying film 11 are removed, and the barrier film 31 on the side faces of each wiring 21 and 25, and the upper faces of the first wiring 21 is removed or thinned. Consequently, the barrier characteristics are maintained by forming the repairing barrier film 32 to repair the barrier film 31 remaining on the side face of each wiring as well as, the harmful effect (an increase of dielectric constant) to the barrier film mediating in the interlayer insulation layer 33 is prevented by keeping this repairing barrier film 32 as thin as possible. In addition, other than SiC, insulating layer, such as SiCO, SiCN, or SiN, may be used as the material for the repairing barrier film 32. Also, the upper barrier film 31 and the repairing barrier film 32 described later constitute the upper diffusion barrier film referred in the claim, and the upper barrier film 31 and the repairing barrier film 32 correspond to the first diffusion barrier film and the second diffusion barrier film respectively.

### (Step 8: Forming of an Interlayer Insulating Film 33)

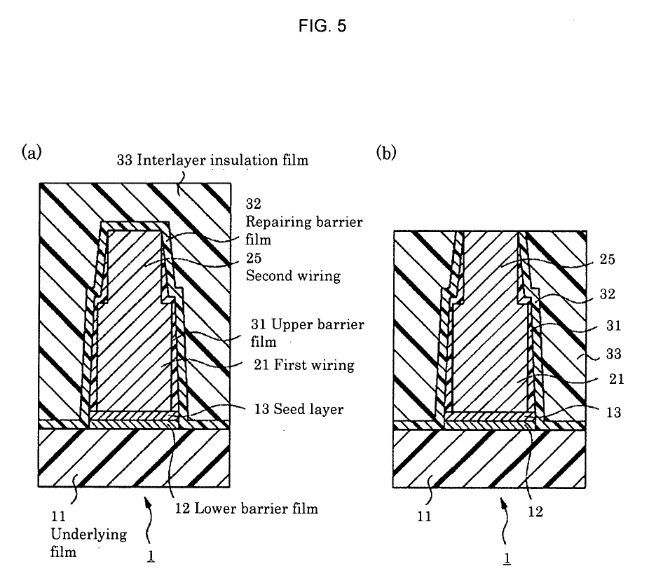

Thereafter, apply, for example, a forming material of the interlayer insulation film 33 on the repairing film 32, and form the interlayer insulation film 33 in a way that covers the repairing barrier 32 (FIG. 5 (a)). Thereafter, remove the surface of the interlayer insulation film 33 and the repairing film 32 until the surface of the second wiring 25 is exposed by, for example, CMP, thereby a wiring circuit layer portion is formed (FIG. 5 (b)).

According to the embodiment described above, after the first wiring 21 is formed in the resist pattern 15 of the resist film 14 formed on the substrate 1 and then the second wiring 25 is formed in the resist pattern 23 of the resist film 22 provided on the resist film 14 after forming the first wiring 21, the resist films 14 and 22 are removed, the barrier films 31 and 32 are formed around the first wiring 21 and the second wiring 25, and the interlayer insulation film 33 is formed so as to surround the barrier film 31 and 32, thereby the projection domain of the second wiring 25 to the substrate is smaller than the projection domain of the first wiring 21 to the substrate. Therefore, in order to form the first wiring and the second wiring in the interlayer insulation film in the conventional dual damascene process, it is necessary to perform a process that etching or ashing the interlayer insulation film 33 by using plasma under an environment in which the plasma is generated, however, in this embodiment described above, since the interlayer insulation film 33 is formed so as to cover the wiring after forming the first wiring 21 and the second wiring 25 as described above, the damage to the interlayer insulation film 33 is prevented because there's no necessity for such a process. Also, since the projection domain of the second wiring 25 to the substrate 1 is smaller than the projection domain of the first wiring 21 to the substrate 1, the second wiring acts as a mask when removing the resist film, thereby preventing the resist films 14 and 22 from remaining around the first wiring 21. As a result, an increase in parasitic capacity of the interlayer insulation film 33 coating the first wiring 21 and the second wiring 25 may be prevented, and also the reliability of the wiring may be improved. Also, a decrease in yield of the semiconductor device, which is formed by using these wirings, may be prevented.

Also, according to this embodiment, the interlayer insulation film 33 is simultaneously formed around the first wiring 21 and the second wiring 25, thereby through-put may be improved compared to the method of forming the interlayer insulation film 33 around each wiring separately. Also, since the removal of the resist films 14 and 22 is performed by wet etching, the damage to the wiring 21 and 25 may be prevented compared to ashing using plasma.

Also, the first sacrificial film and the second sacrificial film is not limited to being formed by the resist, it may be another organic film or inorganic film, and for example, it may be constituted with an insulator and form a pattern on this insulator by a lithography etching process, however, it is preferable to constitute by selecting a material that does not react with the metal consisting of the first wiring 21 and the second wiring 25. Further, the first sacrificial film and the second sacrificial film is preferably formed from an identical substance as described in the embodiment above to simplify the process by removing simultaneously after forming the first wiring 21 and the second wiring 25.

In addition, in the embodiment described above, it is not necessary to perform an anisotropic etching, such as dry etching, to remove the resist film 14 and the resist film 23, that are the sacrificial films, thereby, a removal process which is capable of preventing the deterioration of the first wiring 21 and the second wiring 25 can be selected due to a high degree of freedom in the removal process. For example, when the first sacrificial film and the second sacrificial film are constituted by an organic matter, such as a resist film, as described in the embodiment above, it is preferable to remove by wet etching as described above, and also the removal process of each sacrificial film may be performed by forming a reduction system plasma or radical atmosphere if the deterioration of the metal consisting of the wiring can be prevented. In addition, when the first sacrificial film and the second sacrificial film consists of, for example, SiO2 series inorganic materials, it is preferable to perform the removal process of each sacrificial film by wet etching using, for example, HF (fluorine) to reduce the damage to the first wiring 21 and the second wiring 25.

Forming of the interlayer insulating film 33 may be performed, for example, by CVD, and the second wiring 25 may be exposed by performing an etch back of the dry etching instead of CMP to remove any unnecessary surface portion of the interlayer insulating film 33 after forming the interlayer insulation film 33.

Also, when the barrier films 31 and 32 are insulators as shown in FIG. 5 (b), the barrier film 31 covering the upper portion of the second wiring must be removed because the contact resistance increases when, for example, a further lamination of an upper layer wiring on the second wiring 25 is performed. However, when the barrier films 31 and 32 are constituted, for example of a metal with conductivity, any unnecessary surface portions of the interlayer insulation film 33 may be removed by etching or CMP until the barrier films 31 and 32 are exposed.

Also, the first wiring 21 and the second wiring 25 are not limited to being formed by performing electrolyte plating in the embodiment described above, it may be formed, for example, by nonelectrolytic plating. For example, instead of forming the seed layer 13 on the lower barrier film 12, a catalytic layer for nonelectrolytic plating is formed, and constituted, for example by Pb, and forms the resist pattern 15 as the embodiment described above after forming the catalytic layer. Consequently, performing the nonelectrolytic plating by dipping the substrate 1 into a solution containing, for example, Cu ions, thereby forming the wiring 21 by depositing Cu on the catalytic layer with the catalytic ability of the catalytic layer. Thereafter, forming the resist pattern 23 as the embodiment described above, and then performing the nonelectrolytic plating by dipping the substrate 11 into the solution containing Cu ions again, thereby forming the wiring 25 by depositing Cu on the wiring 21. By using such methods, the plating film also grows upward in the resist pattern 15 and 23 as described in the embodiment above, thereby the formation of any voids in the first wiring 21 and the second wiring 25 can be prevented.

In addition, in the embodiment described above, after removing the resist films 14 and 22 as shown in FIG. 3 (c), perform an etching using the first wiring 21 as a mask to expose the underlying film 11 by removing the exposed seed layer 13 and the lower barrier film 12, then form the upper barrier film 31 so as to coat the underlying film 11, the first wiring 21, and the second wiring 25, and after that, the interlayer insulation film 33 may be formed so as to coat the upper barrier film 31 without forming, for example, the repairing barrier film 32. In this case, when etching the seed layer 13 and the lower barrier film 12, for example, form the first wiring 21 and the second wiring 25 larger in advance considering the amount required to etch the first wiring 21 and the second wiring 25.

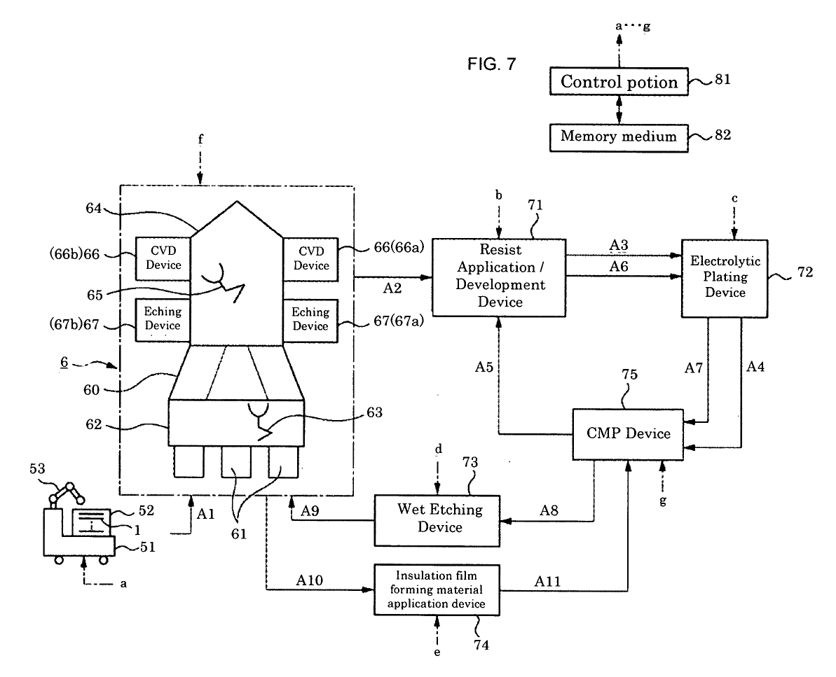

Next, a substrate processing system to embody the manufacturing method of the semiconductor device for the embodiment explained at first is explained in detail referring to FIG. 7. FIG. 7 shows an outline drawing in a clean room provided with the substrate processing system. 51 in the figure is an automated transfer robot that configures the substrate processing system and moves within the clean room to transfer a carrier 52 which stores a plurality of substrates 1, between each device (semiconductor manufacturing device) included in the substrate processing system described later. 53 in the figure is a transfer arm to perform the transfer.

And, a multi-chamber system 6 which consists of a portion of the constituent of the substrate processing system, is explained. 61 is a placing portion for the carrier 52, and 62 in the figure is a loading portion provided with a first transfer arm 63 to take out the substrate 1 from the carrier 52. 64 in the figure is a vacuum transfer chamber provided with a second transfer arm 65 to transfer the substrate 1 with the first transfer arm 63, and the moving area of the second transfer arm 65 in this vacuum transfer chamber 64 remains at a vacuum at all times. 60 in the figure is a load lock chamber to connect the loading portion and the vacuum transfer chamber, and vacuum and normal pressure can be switched in the load lock chamber 60. The substrate 1 is transferred between the transfer arm 63 and the transfer arm 65 through this load lock chamber 60.

Various vacuum processing devices, which are provided with a processing container and capable of adjusting the pressure inside the processing container, are provided around the vacuum transfer chamber 64. A CVD device 66 for forming various films on the substrate 1, and an etching device 67 for dry etching are provided as the vacuum processing devices, and the transfer arm 65 transfers the substrate 1 between these vacuum processing devices.

71 in the figure is a resist application/development device to apply resist on the surface of the substrate 1 and for forming a predetermined pattern by developing the resist. 72 in the figure is an electrolytic plating device to form a copper wire by performing the electrolytic plating as described above. 73 in the figure is a wet etching device to remove the resist films 14 and 22, and 74 in the figure is an insulation film forming material application device to apply an insulation film forming material for forming the interlayer insulation film 33 on the substrate 1. 75 in the figure is a CMP device.

The substrate processing system described above is provided with subordinate computers to control the motion of each device, and further provided with a control portion 81, which is a host computer to control each subordinate computer. The control portion 81 has a data processing portion and the like consisting of a program, memory, and CPU. The program stored in the host computer is configured as a transfer sequence program for transferring the substrate 1 between each device, and the subordinate computers store a program for performing the above described process for forming wiring circuit layer portions including the interlayer insulation film 33 and wires 21 and 25 that comprise one or more layers on the substrate 1. By the program stored in the host computer as shown in “a” to “g” in the figure, the control portion 81 transmits a control signal to each device in the substrate processing system, and subordinate computers of each device receives this control signal controlling the motion of each part of each device.

The program described above may be stored in a memory media 82 consisting of, for example, a flexible disk, a compact disk, and/or a MO (magnetic-optical disk), and installed in the control portion 81.

Next, how the substrate 1 stored in the carrier 52 is transferred to each device of the substrate processing system in a factory, and the wiring and the interlayer insulation film are formed as described above is explained by referring to FIG. 7. Arrows with An (n=1 to 11) connect between each device indicate the paths for transferring the carrier 52 containing the substrate 1 by the automated transfer robot 51. First, the transfer robot 51 transfers the carrier 52 to the multi-chamber system 6 as shown by the arrow A1 in the figure, the substrate 1 in the carrier 52 is brought into the CVD device 66, and the lower barrier film 12 and the seed layer 13 are formed in this CVD device 66 as shown in, for example, FIG. 1 (a), (b). In addition, forming processes for the lower barrier film 12 and the seed layer 13 may be performed in a separate chamber, and for example, it may be performed by the CVD devices 66a and 66b.

Consequently, the carrier 52, which has the substrate 1 processed in the multi-chamber system 6, transfers it to the resist application/development device 71 as indicated by the arrow A2, and the resist film 14 and the resist pattern 15 are formed on the substrate 1 by this application/development device 71 (FIG. 1 (c), (d)).

In order to simplify the description in the explanation, an expression “the substrate 1 is transferred” is hereinafter used. Next, on the substrate 1 processed in the application/development device 71 as shown by the arrow A3 in FIG. 7, the plating film 16 is formed in the electrolytic plating device 72, then transferred to CMP device 75 as shown by the arrow A4 to form the first wire 21 (FIG. 2(b)). Thereafter, the substrate 1 is returned to the resist application/development device 71 as shown by arrow A5, and the resist film 22 and the resist pattern 23 are formed (FIG. 2 (c), (d)).

And, after the substrate 1 is transferred to the electrolytic plating device 72 and the plating film 24 is formed as shown by the arrow A6, (FIG. 3 (a)), then transferred to CMP device 75 as shown by the arrow A7 and the second wiring 25 is formed (FIG. 3 (b)). After forming the second wiring 25, the substrate 1 is transferred to the wet etching device 73 shown by the arrow A8, and the resist films 14 and 22 are removed by the device 73 (FIG. 3 (c)).

Thereafter, the substrate 1 is transferred to the multi-chamber system 6 again as shown by the arrow A9, and processed by transferring between the etching device 67 and the CVD device 66, thereby the process shown in FIG. 4 (a) to (c) is performed, and the barrier films 31, 32 coating each wire 21, 25 are formed.

Thereafter, the substrate 1 is transferred to the insulation film forming material application device 74 as shown by the arrow A10, and the interlayer insulation film 33 is formed therein (FIG. 5(a)), then transferred to the CMP device 75 as shown by the arrow A11. In the device 75, the CMP is performed to form the wiring circuit layer portion as shown in FIG. 5 (b).

What is claimed is:

1. A manufacturing method of a semiconductor device for forming a first wiring and a second wiring that is laminated on the first wiring to electrically connect the first wiring and a wiring on an upper layer, in an interlayer insulation film, the method comprising the steps of:
forming a conductive lower diffusion barrier film on a substrate to prevent a metal comprising the first wiring from diffusing into a lower interlayer;
forming a first sacrificial film on said lower diffusion barrier film, and forming a first pattern, which is a depression corresponding to the first wiring on the first sacrificial film;
filling a metal in said first pattern and forming the first wiring;
forming a second sacrificial film on the first sacrificial film and the first wiring, and forming a second pattern, which is a depression corresponding to the second wiring, on the second sacrificial film so as to expose the first wiring;
filling a metal in said second pattern, and forming the second wiring;
removing the first sacrificial film and the second sacrificial film;
forming an upper diffusion barrier film coating the first wiring and the second wiring to prevent a metal comprising each wiring from diffusing into the interlayer insulation film; and
forming the interlayer insulation film so as to coat the upper diffusion barrier film;
wherein a projection domain of the second wiring to the substrate is smaller than the projection domain of the first wiring to the substrate.

2. The manufacturing method of the semiconductor device according to claim 1, wherein the step for forming said upper diffusion barrier film comprises a step for forming said upper diffusion barrier film, which is an insulation film, so as to cover the first wiring, the second wiring, and the lower diffusion barrier film.

3. The manufacturing method of the semiconductor device according to claim 1, wherein said upper diffusion barrier film comprises a first diffusion barrier film and a second diffusion barrier film, and the step for forming said upper diffusion barrier film further comprises the steps of;
forming said first diffusion barrier film so as to coat the first wiring and the second wiring;
etching said first diffusion barrier film and the lower diffusion barrier film; and
forming said second diffusion barrier film, which is an insulation film to cover the first wiring, the second wiring, and a substrate surface.

4. The manufacturing method of the semiconductor device according to claim 3, wherein a thickness of said second diffusion barrier film ranges between 5 to 30 nm.

5. The manufacturing method of the semiconductor device according to claim 1, the method further comprising the step of:
providing a seed layer, which is a conductor, on the lower diffusion barrier film before forming the first sacrificial film;
wherein the step for forming the first wiring is performed by an electrolytic plating to apply a voltage to the seed layer.

6. The manufacturing method of the semiconductor device according to claim 5, wherein the step for forming said second wiring is performed by an electrolytic plating to apply a voltage to the first wiring through said seed layer.

7. The manufacturing method of the semiconductor device according to claim 1, wherein the removal of the first sacrificial film and the second sacrificial film is performed by a wet etching.

8. The manufacturing method of the semiconductor device according to claim 1, wherein said first sacrificial film and said second sacrificial film comprise a same material.

9. A semiconductor device having a first wiring and a second wiring that is laminated on the first wiring to electrically connect the first wiring and a wiring on an upper layer, in an interlayer insulation film, and the semiconductor device is manufactured by a method comprising the steps of:
forming a conductive lower diffusion barrier film on a substrate to prevent a metal comprising the first wiring from diffusing into a lower interlayer;
forming a first sacrificial film on said lower diffusion barrier film, and forming a first pattern, which is a depression corresponding to the first wiring, on the first sacrificial film;
filling a metal in said first pattern and forming the first wiring;
forming a second sacrificial film on the first sacrificial film and the first wiring, and forming a second pattern, which is a depression corresponding to the second wiring, on the second sacrificial film so as to expose the first wiring;
filling a metal in said second pattern, and forming the second wiring;
removing the first sacrificial film and the second sacrificial film;
forming an upper diffusion barrier film coating the first wiring and the second wiring to prevent a metal comprising each wiring from diffusing into the interlayer insulation film; and
forming the interlayer insulation film so as to coat the upper diffusion barrier film;
wherein a projection domain of the second wiring to the substrate is smaller than a projection domain of the first wiring to the substrate.

10. The semiconductor device according to claim 9, wherein the step for forming said upper diffusion barrier film comprises a step for forming said upper diffusion barrier film, which is an insulation film, so as to cover the first wiring, the second wiring, and the lower diffusion barrier film.

11. The semiconductor device according to claim 9, wherein said upper diffusion barrier film comprises a first diffusion barrier film and a second diffusion barrier film and the steps for forming said upper diffusion barrier film further comprises the steps of;
forming said first diffusion barrier film so as to coat the first wiring and the second wiring;
etching said first diffusion barrier film and the lower diffusion barrier film; and
forming said second diffusion barrier film, which is an insulation film, to cover the first wiring, the second wiring, and a substrate surface.

12. The semiconductor device according to claim 11, wherein a thickness of said second diffusion barrier film ranges between 5 to 30 nm.

13. The semiconductor device according to claim 9, the method further comprising the step of:
providing a seed layer which is a conductor, on the lower diffusion barrier film before forming the first sacrificial film;
wherein the step for forming the first wiring is performed by an electrolytic plating to apply a voltage to the seed layer.

14. The semiconductor device according to claim 13, wherein the step for forming said second wiring is performed by an electrolytic plating to apply a voltage to the first wiring through said seed layer.

15. The semiconductor device according to claim 9, wherein said removal of said first sacrificial film and said second sacrificial film is performed by a wet etching.

16. The semiconductor device according to claim 9, wherein said first sacrificial film and said second sacrificial film comprise a same material.

17. A substrate processing system for manufacturing a semiconductor device comprising a plurality of semiconductor manufacturing device groups, wherein a control portion is provided to control the manufacturing method of the semiconductor device according to claim 9.

18. A memory medium for storing a program to control a plurality of semiconductor manufacturing devices, wherein the program operates on a computer, and a semiconductor device having a first wiring and a second wiring that is laminated on the first wiring to electrically connect the first wiring and a wiring on an upper layer, in an interlayer insulation film is manufactured when the program is executed by a method comprising steps of:
forming a conductive lower diffusion barrier film on a substrate to prevent a metal comprising the first wiring from diffusing into a lower interlayer;
forming a first sacrificial film on said lower diffusion barrier film, and forming a first pattern, which is a depression corresponding to the first wiring on the first sacrificial film;
filling a metal in said first pattern and forming the first wiring;
forming a second sacrificial film on the first sacrificial film and the first wiring, and forming a second pattern, which is a depression corresponding to the second wiring, on this second sacrificial film so as to expose the first wiring;
filling a metal in said second pattern, and forming the second wiring;
removing the first sacrificial film and the second sacrificial film;
forming an upper diffusion barrier film coating the first wiring and the second wiring to prevent a metal comprising each wiring from diffusing into the interlayer insulation film; and
forming the interlayer insulation film so as to coat the upper diffusion barrier film;
wherein a projection domain of the second wiring to the substrate is smaller than a projection domain of the first wiring to the substrate.

19. The substrate processing system for manufacturing the semiconductor device according to claim 18, wherein the system comprising a control portion to control said memory medium comprises a plurality of device groups.
